(19) United States
(12) Patent Application Publication
(10) Pub. No.: US 2026/0293053 A1
(43) Pub. Date: Sep. 24, 2026

(54) PORTABLE HYBRID HEAT DISSIPATION MODULE, HIGH HEAT FLUX ELECTRONIC DEVICE, AND TEST METHOD THEREOF

(71) Applicant: Wistron Corporation, New Taipei City (TW)

(72) Inventors: YU JEI HUANG, New Taipei City (TW); YUCHUAN WU, New Taipei City (TW)

(21) Appl. No.: 19/267,719

(22) Filed: Jul. 14, 2025

(30) Foreign Application Priority Data
Mar. 20, 2025 (TW) 114110479

(51) Int. Cl. H05K 7/20

(52) U.S. Cl. CPC H05K 7/20327

(57) ABSTRACT

A portable hybrid heat dissipation module, a high heat flux electronic device, and a test method thereof are provided. The portable hybrid heat dissipation module includes a boiling enhancement coating plate, a housing formed with a two-phase chamber and combined with the boiling enhancement coating plate to seal the two-phase chamber, and a cooling mechanism disposed on the housing corresponding to the two-phase chamber.

### CROSS-REFERENCE TO RELATED APPLICATION

This application claims the priority benefits of Taiwan patent application serial no. 114110479, filed on Mar. 20, 2025. The entirety of the mentioned above patent application is hereby incorporated by reference herein and made a part of this specification.

### BACKGROUND OF THE DISCLOSURE

### 1. Field of the Disclosure

The disclosure is related to a portable hybrid heat dissipation module; more specifically, the disclosure is related to a portable hybrid heat dissipation module that dissipates heat through phase change and heat exchange, a high heat flux electronic device including the portable hybrid heat dissipation module, and a test method for testing the heat dissipation performance of the portable hybrid heat dissipation module.

### 2. Related Art

The two-phase heat dissipation solution is one of the novel technologies applied to heat dissipation of servers in recent years. It effectively enhances heat dissipation through a highly efficient phase change phenomenon to solve the heat dissipation problem of chips with increasingly higher heat density (or heat flux). However, the two-phase liquid used in two-phase heat dissipation is generally a special liquid having low-boiling temperature, and is therefore extremely expensive and easily volatile. At the same time, heat sinks or heat dissipation modules need to undergo 100% performance inspection and testing before shipment. This means that manufacturers not only have to build new inspection equipment for two-phase heat dissipation, but also have to face the problem of large amounts of loss of the two-phase liquid caused by the inspection.

In addition, the heat dissipation modules or test devices on the market generally have the problem of being too large in size, and cannot be customized and simplified according to the size of a single two-phase heat sink.

### SUMMARY OF THE DISCLOSURE

It is an object of the disclosure to provide a portable hybrid heat dissipation module, which dissipates heat through phase change and heat exchange and is suitable for high heat flux (or high heat-generating) electronic components.

It is another object of the disclosure to provide a portable hybrid heat dissipation module, which integrates the housing having the two-phase chamber with the cooling mechanism to minimize the overall volume, thereby reducing the usage and consumption of the two-phase fluid and promoting the overall structural strength to enhance the air-tightness.

It is a further object of the disclosure to provide a portable hybrid heat dissipation module, which utilizes the boiling enhancement coating plate with the boiling enhancement coating (BEC) as the cover of the housing of the heat dissipation module to seal the two-phase chamber, thereby reducing the number of components and achieving the air-tight effect.

It is yet another object of the disclosure to provide a portable hybrid heat dissipation module, which can adjust the boiling temperature of the two-phase fluid by adjusting the pressure in the two-phase chamber, thereby expanding the applicable two-phase fluids and selecting a more economical two-phase fluid.

In an embodiment, the disclosure provides a portable hybrid heat dissipation module, which includes a boiling enhancement coating plate, a housing, and a cooling mechanism; the housing is formed with a two-phase chamber and combined with the boiling enhancement coating plate to seal the two-phase chamber; the cooling mechanism is disposed on the housing corresponding to the two-phase chamber.

In an embodiment, the cooling mechanism includes a coolant inlet, a coolant outlet, and a coolant flowing space. The coolant inlet and the coolant outlet are formed on the housing. The coolant flowing space communicates the coolant inlet with the coolant outlet and is adjacent to the two-phase chamber or located in the two-phase chamber.

In an embodiment, the cooling mechanism includes a plurality of first fins disposed on the housing and located outside the two-phase chamber.

In an embodiment, the cooling mechanism further includes a plurality of second fins disposed on the housing and located in the two-phase chamber.

In an embodiment, the portable hybrid heat dissipation module of the disclosure further includes a gasket, wherein the housing has a chamber opening communicating with the two-phase chamber. The gasket is disposed between the housing and the boiling enhancement coating plate and surrounds the chamber opening.

In an embodiment, the housing has a groove. The groove is disposed surrounding the chamber opening, and the gasket is disposed in the groove.

In an embodiment, the portable hybrid heat dissipation module of the disclosure further includes a fluid inlet, wherein the fluid inlet is disposed on the housing and communicates with the two-phase chamber. The fluid inlet allows a work fluid to flow into the two-phase chamber.

In an embodiment, the portable hybrid heat dissipation module of the disclosure further includes a control valve, wherein the control valve is disposed on the housing corresponding to the fluid inlet and controls communication of the two-phase chamber with an external environment through the fluid inlet.

In an embodiment, the fluid inlet may selectively function as a gate to adjust the pressure in the two-phase chamber.

In an embodiment, the portable hybrid heat dissipation module of the disclosure further includes a coupling member. The coupling member combines the housing with the boiling enhancement coating plate to enable the two-phase chamber to become an air-tight space.

In an embodiment, the boiling enhancement coating plate includes a boiling enhancement coating and a frame, wherein the frame supports the boiling enhancement coating, and the coupling member fixes the frame on the housing.

In an embodiment, the coupling member includes a screw, a locking member, or a combination thereof.

In another embodiment, the disclosure provides a high heat flux electronic device, which includes the portable hybrid heat dissipation module described above and a high heat flux electronic component, wherein the high heat flux electronic component is combined with the boiling enhancement coating plate and located outside the housing.

In an embodiment, the portable hybrid heat dissipation module further includes a fluid inlet. The fluid inlet is disposed on the housing and communicates with the two-phase chamber. The fluid inlet may selectively function as a gate to adjust the pressure in the two-phase chamber.

In an embodiment, the boiling enhancement coating plate includes a boiling enhancement coating and a frame. The frame supports the boiling enhancement coating and is fixed on the housing. The high heat flux electronic component is combined with the boiling enhancement coating.

In yet another embodiment, the disclosure provides a test method of a portable hybrid heat dissipation module, which includes using the portable hybrid heat dissipation module described above, combining the boiling enhancement coating plate with the housing to seal the two-phase chamber, introducing a work fluid into the two-phase chamber, heating the boiling enhancement coating plate with a predetermined amount of heat, and measuring the temperature of the boiling enhancement coating plate to determine the heat dissipation performance of the boiling enhancement coating plate.

In an embodiment, in the step of introducing the work fluid, the work fluid is introduced up to 75% of the volume of the two-phase chamber.

In an embodiment, the step of introducing the work fluid includes introducing a dielectric fluid, semi-conductive fluid, or conductive fluid with a boiling temperature greater than or equal to 45° C. and less than or equal to 250° C. at the atmosphere pressure.

In an embodiment, the step of introducing the work fluid includes fluoride liquid, water, propylene glycol, or ethylene glycol in liquid phase.

In an embodiment, the test method of the disclosure further includes: adjusting the pressure in the two-phase chamber to adjust the boiling temperature of the work fluid.

### BRIEF DESCRIPTION OF THE DRAWINGS

FIG. 1A is an exploded view of the portable hybrid heat dissipation module in an embodiment of the disclosure.

FIG. 1B is an assembly view of the portable hybrid heat dissipation module of FIG. 1A.

FIG. 2 is a schematic view of the portable hybrid heat dissipation module in another embodiment of the disclosure.

FIG. 3 is a schematic view of the portable hybrid heat dissipation module in yet another embodiment of the disclosure.

FIG. 4 is a schematic view of the portable hybrid heat dissipation module in a further another embodiment of the disclosure.

FIG. 5A is a cross-sectional view of the high heat flux electronic device in an embodiment of the disclosure.

FIG. 5B is an exploded view of the high heat flux electronic device in an embodiment of the disclosure.

FIG. 6 is a schematic operation view of the test method of the portable hybrid heat dissipation module in an embodiment of the disclosure.

FIG. 7 is a flow chart of the test method of the portable hybrid heat dissipation module in an embodiment of the disclosure.

### DETAILED DESCRIPTION OF THE PREFERRED EMBODIMENT

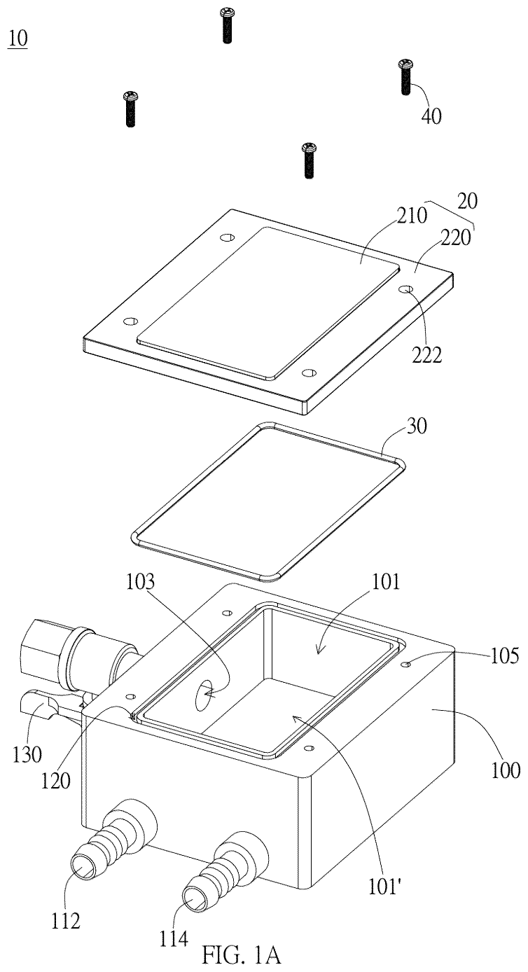

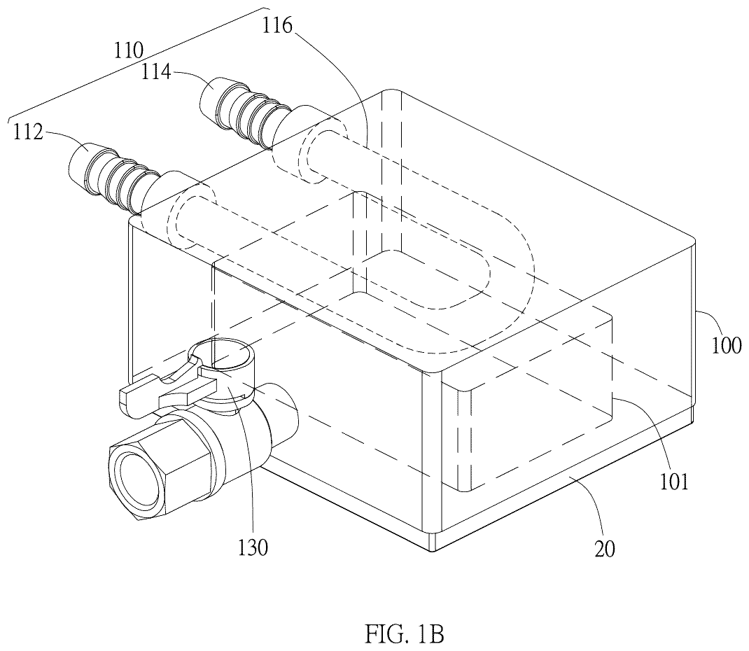

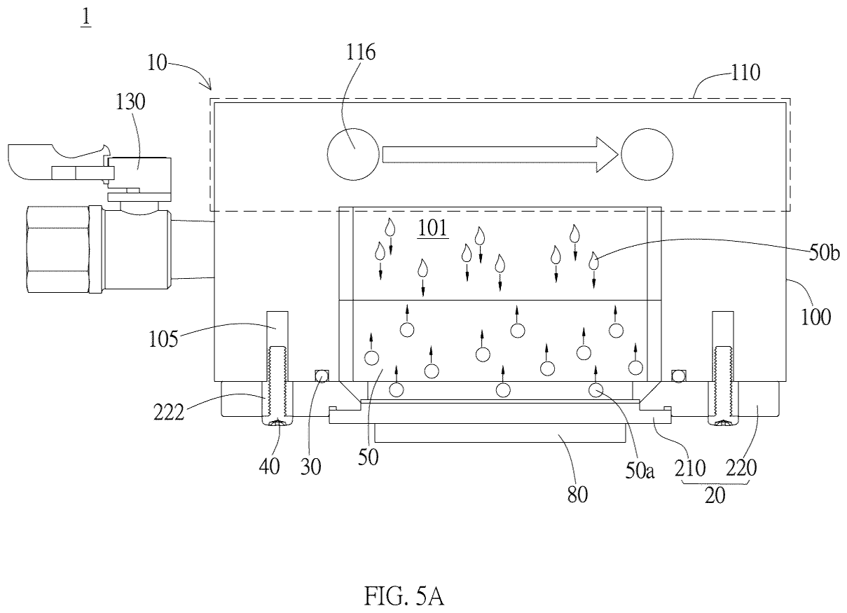

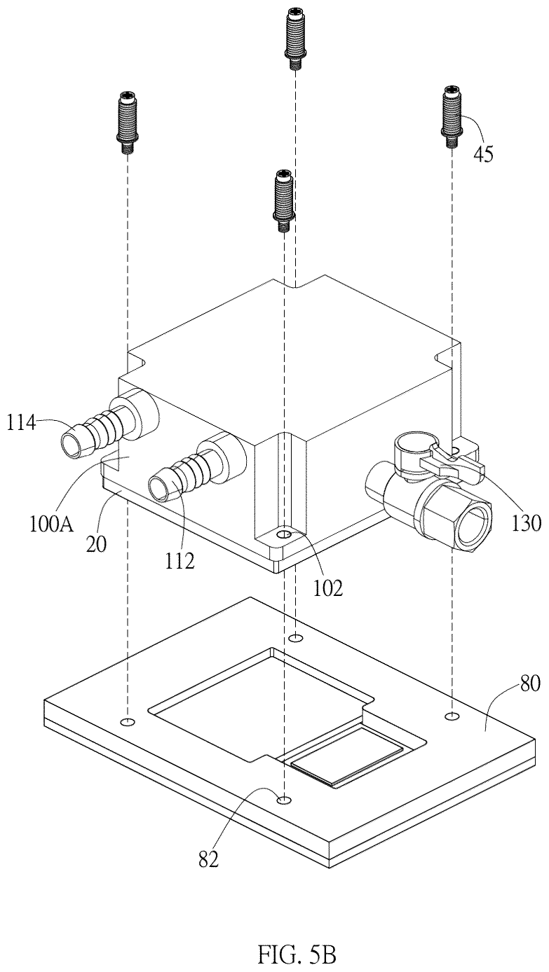

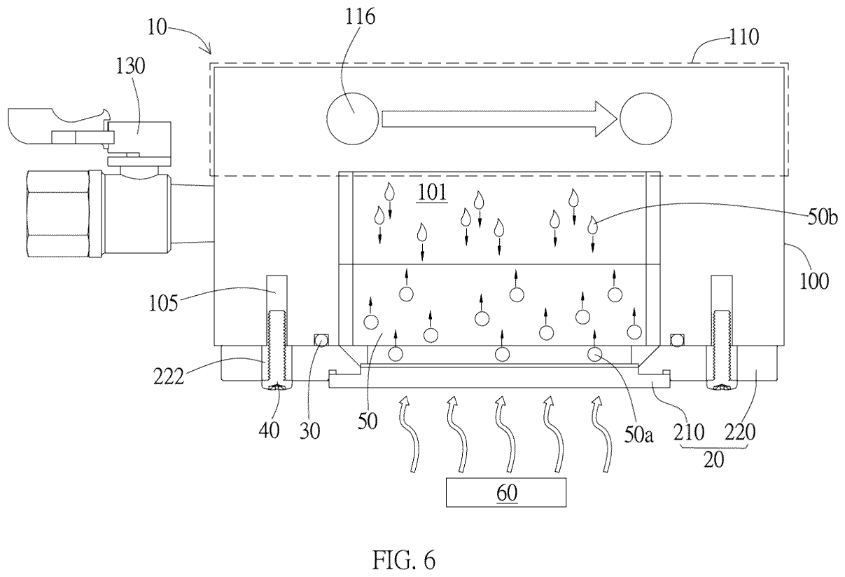

Referring to FIG. 1A and FIG. 1B, FIG. 1A is an exploded view of the portable hybrid heat dissipation module 10 in an embodiment of the disclosure, and FIG. 1B is an assembly view of the portable hybrid heat dissipation module 10 of FIG. 1A. As shown in FIG. 1A and FIG. 1B, the portable hybrid heat dissipation module 10 includes a boiling enhancement coating plate 20, a housing 100, and a cooling mechanism 110. The boiling enhancement coating plate 20 includes a boiling enhancement coating (BEC) 210. The housing 100 is formed with a two-phase chamber 101. The housing 100 is combined with the boiling enhancement coating plate 20 to seal the two-phase chamber 101. The cooling mechanism 110 is disposed on the housing 100 and corresponds to the two-phase chamber 101. The cooling mechanism 110 enables the work fluid 50 (shown in FIG. 5A and FIG. 6), which experiences the phase change in the two-phase chamber 101, to restore the phase state before the phase change.

Specifically, the boiling enhancement coating plate 20 may be a boiler plate including the boiling enhancement coating 210. In this embodiment, the boiling enhancement coating plate 20 may further include a frame 220. The frame 220 supports the boiling enhancement coating 210 and to be fixed on the housing 100. The boiling enhancement coating 210 is generally formed by metal, such as copper, aluminum, or alloys thereof, and may have a porous surface. Moreover, the boiling enhancement coating 210 can be mounted on the center of the frame 220 by any suitable manner, such as welding/soldering, engaging, screwing, pressing, so that the boiling enhancement coating plate 20 can have an integral compact structure. For example, the boiling enhancement coating 210 can be fixed on the frame 220 by high temperature welding. In general, the boiling enhancement coating plate 20 is installed on a high heat flux component, such as central the processing unit (CPU) or the graphic processing unit (GPU) in a server, to reduce the boiling resistance of the work fluid 50 and meet the heat flux requirements of such components.

The housing 100 is formed with the two-phase chamber 101 therein, and the housing 100 has a chamber opening 101′, which communicates with the two-phase chamber 101. In this embodiment, the two-phase chamber 101 is preferably centrally located in the housing 100, and the two-phase chamber 101 extends to the surface of the housing 100 to form the chamber opening 101′. For example, the two-phase chamber 101 can be a space surrounded by a plurality of sidewalls of the housing 100, and one side of the housing 100 is not completely surrounded by the sidewall, so that the chamber opening 101′ is formed on the surface of the housing 100 and communicates with the two-phase chamber 101. From another aspect, the housing 100 may have a “U”-shaped cross section. The space enclosed in the U-shaped profile is the two-phase chamber 101, and the opening of the U-shaped profile is the chamber opening 101′ of the two-phase chamber 101, but not limited thereto. According to practical applications, the housing 100 can have the two-phase chamber 101 opened with any suitable shape. In this embodiment, the size of the chamber opening 101′ preferably corresponds to that of the boiling enhancement coating plate 20, so that the size of the housing 100 corresponding to a single boiling enhancement coating plate 20 can be significantly reduced. For example, the size of the chamber opening 101′ preferably corresponds to that of the boiling enhancement coating 210, so that the boiling enhancement coating plate 20 can serve as a cover, which closes the two-phase chamber 101 by fixing the frame 220 on the sidewall of the housing 100. In other words, the boiling enhancement coating plate 20 is combined with the housing 100 to seal the chamber opening 101′ of the two-phase chamber 101, so that the two-phase chamber 101 can become an air-tight space.

In this embodiment, the cooling mechanism 110 may include a coolant inlet 112, a coolant outlet 114, and a coolant flowing space 116. The coolant inlet 112 and the coolant outlet 114 are formed on the housing 100. The coolant flowing space 116 communicates the coolant inlet 112 with the coolant outlet 114 and is adjacent to the two-phase chamber 101 or located in the two-phase chamber 101. Specifically, the cooling mechanism 110 is disposed at a side of the housing 100 opposite to the chamber opening 101′ of the two-phase chamber 101, such as the horizonal portion (or the bottom) of the U-shaped cross section. The coolant inlet 112 and the coolant outlet 114 are opened on the sidewall of the housing 100. The coolant flowing space 116 communicates the coolant inlet 112 with the coolant outlet 114, so that the coolant can flow into the coolant flowing space 116 in the housing 100 from the coolant inlet 112 and flow out from the coolant outlet 114. In an embodiment, the coolant flowing space 116 can be embodied as a channel or pipe in the housing 100 and is preferably distributed corresponding to the two-phase chamber 101 to facilitate heat exchange of the two-phase fluid (i.e., the work fluid 50), enhancing the cooling efficiency of the cooling mechanism 110. For example, the coolant flowing space 116 can be a U-shaped pipe, an S-shaped pipe, or a multi-bend pipe, but not limited thereto. In an embodiment, the coolant of the cooling mechanism 110 can be water or any suitable coolants. Moreover, the cooling mechanism 110 of the portable hybrid heat dissipation module 10 can be operated with a cooling pump or cooling unit to enhance the cooling efficiency. For example, the cooling unit can cool the coolant having a relatively higher temperature, which exchanges heat with the two-phase fluid (e.g. 50) and flows out from the coolant outlet 114, to a relatively lower temperature. The cooling pump can effectively pump the coolant having a relatively lower temperature into the coolant inlet 112 and out of the coolant outlet 114 to achieve the cooling circulation and enhance the cooling efficiency.

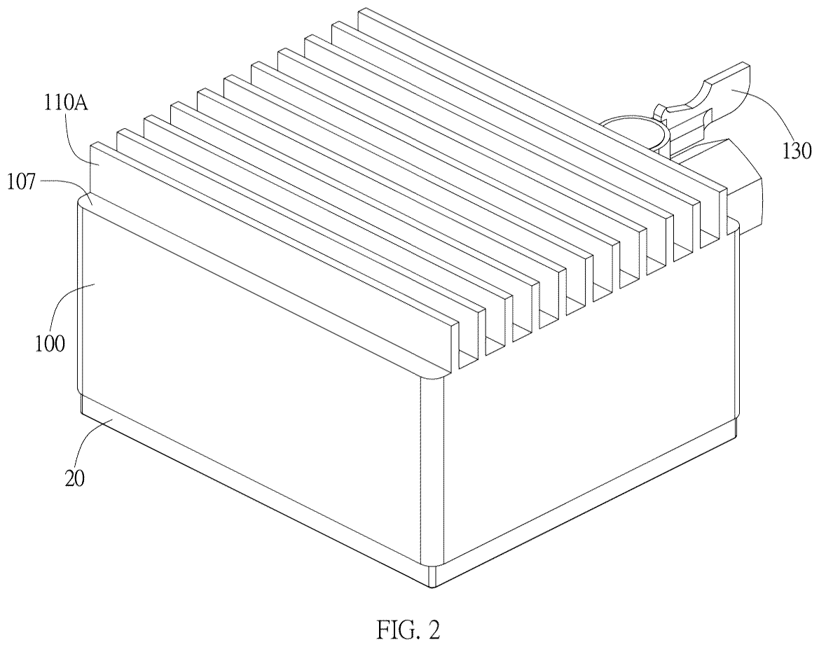

In another embodiment, as shown in FIG. 2, the cooling mechanism may include a plurality of first fins 110A. The plurality of first fins 110A are disposed on the housing 100 and located outside the two-phase chamber 10. For example, the plurality of first fins 110A are preferably disposed on the outer surface 107 of the housing 100, which is opposite to the chamber opening 101′ (or the boiling enhancement coating plate 20) with respect to the two-phase chamber 101, to increase the heat dissipation surface area by the plurality of first fins 110A to achieve the desired heat dissipation effect. The plurality of first fins 110A can dissipate heat through natural convention or forced convention through a fan or a water pump. The shape of the first fins 110A is not limited to the sheet-like or column-like shape, and the first fins 110A may have any structure that can increase the heat dissipation surface area.

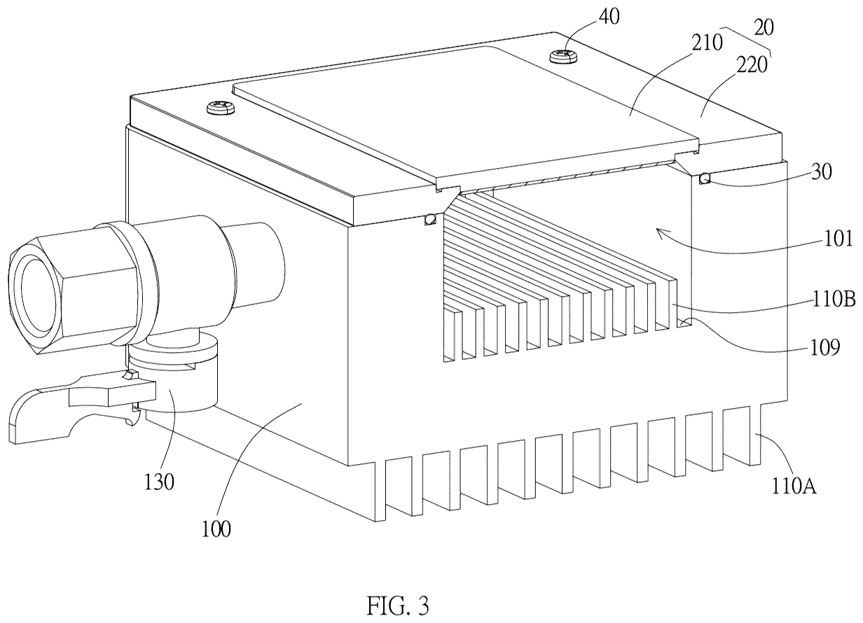

In another embodiment, as shown in FIG. 3, the cooling mechanism may further include a plurality of second fins 110B. The plurality of second fins 110B are disposed on the housing 100 and located in the two-phase chamber 101 to further enhance the cooling effect of the cooling mechanism. Specifically, the plurality of second fins 110B are preferably disposed on the inner surface 109 of the housing 100, which is opposite to the chamber opening 101′ (or the boiling enhancement coating plate 20) with respect to the two-phase chamber 101, to increase the heat dissipation effect of the inner surface in the two-phase chamber 101 and the work fluid 50 in the two-phase chamber 101 by means of the plurality of second fins 110B. For example, the plurality of first fins 110A and the plurality of second fins 110B can be respectively disposed on the outer surface and the inner surface of a same wall of the housing 100, but not limited thereto. In an embodiment, the plurality of first fins 110A and the plurality of second fins 110B are preferably integrated with the housing 100 into an integral structure to achieve the design of minimum volume and promote the overall structural strength. The shape of the second fins 110B is not limited to the sheet-like or column-like shape, and the second fins 110B may have any structure that can increase the heat dissipation surface area. For example, the second fins 110B may have a surface with the chevron pattern, a surface with nicks, or a hydrophobic treated surface to enhance the condensation of droplets.

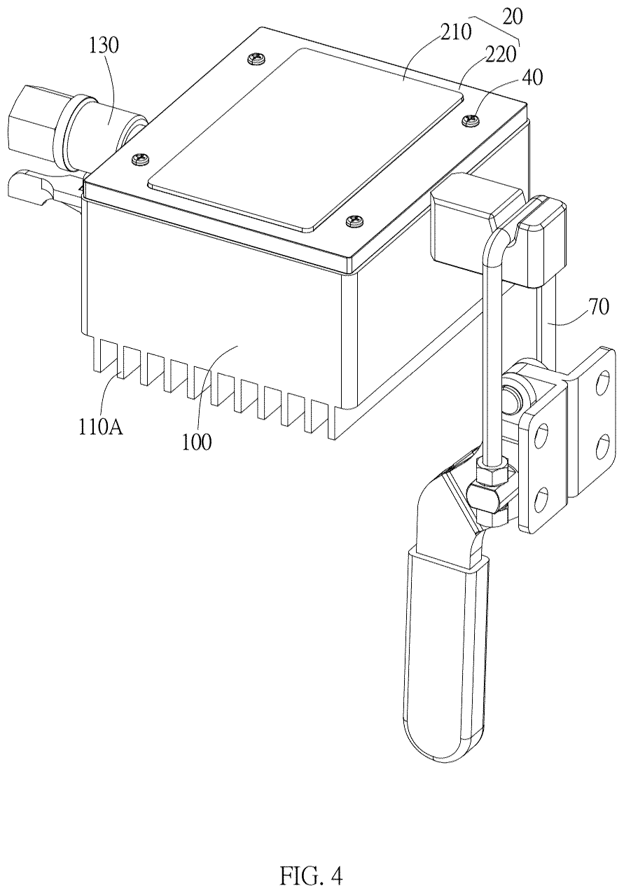

In an embodiment, as shown in FIG. 1A, the portable hybrid heat dissipation module 10 may further include a coupling member (e.g. 40), which combines the housing 100 with the boiling enhancement coating plate 20. For example, the coupling member may include a screw 40 (or bolt). Corresponding to the coupling member in the form of the screw 40 (or bolt), the boiling enhancement coating plate 20 may have a hole 222, for example, formed in the frame 220, and the housing 100 may have a fixing hole 105 on the wall adjacent to the chamber opening 101′. When the boiling enhancement coating plate 20 is combined with the housing 100 to cover the chamber opening 101′, the hole 222 is aligned with the fixing hole 105, and the screw 40 (or bolt) is inserted into the fixing hole 105 through the hole 222 to fix the frame 220 of the boiling enhancement coating plate 20 onto the housing 100, but not limited thereto. In another embodiment, as shown in FIG. 4, the coupling member may be embodied as a locking member 70, wherein the housing 100 and the boiling enhancement coating plate 20 have corresponding engaging structures. When the boiling enhancement coating plate 20 covers the chamber opening 101′ and is combined with the housing 100, the locking member 70 secures the corresponding engaging structures together. It is noted that the boiling enhancement coating plate 20 can be combined with the housing 100 by any one or both of the screw 40 and the locking member 70.

In an embodiment, as shown in FIG. 1A, the portable hybrid heat dissipation module 10 may further include a gasket 30. The gasket 30 is disposed between the housing 100 and the boiling enhancement coating plate 20 and surrounds the chamber opening 101′. The gasket 30 enhances the connection tightness between the housing 100 and the boiling enhancement coating plate 20 or the air-tightness of the two-phase chamber 101. Specifically, the housing 100 may have a groove 120, which is disposed surrounding the chamber opening 101′. The gasket 30 is disposed in the groove 120 to accurately position the gasket 30. In an embodiment, the gasket 30 is made of elastic material, such as rubber, silicone, but not limited thereto. When the boiling enhancement coating plate 20 and the housing 100 are combined, the boiling enhancement coating plate 20 may abut against the gasket 30 to increase the connection tightness with the housing 100.

Moreover, as shown in FIG. 1A, the portable hybrid heat dissipation module 10 may further include a fluid inlet 103. The fluid inlet 103 is disposed on the housing 100 and communicates with the two-phase chamber 101. The fluid inlet 103 allows the work fluid 50 to flow into the two-phase chamber 101. Specifically, the fluid inlet 103 is formed in the wall of the housing 100. For example, the fluid inlet 103 is preferably formed in a wall that is different from the wall on which the cooling mechanism 110 (or the first fins 110A and the second fins 110B) are disposed. The fluid inlet 103 communicates the two-phase chamber 101 with the external environment, such as the supply source of the work fluid 50 or the vacuum generator. For example, the fluid inlet 103 can be a channel that penetrates through the wall (e.g. sidewall) of the housing 100 and allows the work fluid 50 to flow into the two-phase chamber 101. Specifically, the portable hybrid heat dissipation module 10 may further include a control valve 130. The control valve 130 is disposed on the housing 100 corresponding to the fluid inlet 103 and controls the communication of the two-phase chamber 101 with the external environment through the fluid inlet 103. In an embodiment, the control valve 130 may be connected to the supply source of the work fluid 50 and the fluid inlet 103 and control the amount of the work fluid 50 introduced into the two-phase chamber 101 by opening or closing the control valve 130. For example, the amount of the work fluid 50 introduced into the two-phase chamber 101 can be up to 75% of the volume of the two-phase chamber 101, and preferably up to 50% of the volume of the two-phase chamber 101. The work fluid 50 is preferably a liquid (such as fluoride liquid) that generally has a low boiling temperature at the atmospheric pressure, such as lower than 60° C., and is easy to evaporate, but not limited thereto.

In another embodiment, the fluid inlet 103 can selectively function as a gate for adjusting the pressure in the two-phase chamber 101. Specifically, the control valve 130 can be selectively connected to a vacuum generator, such as a vacuum pump, and the fluid inlet 103 to adjust the pressure in the two-phase chamber 101 by controlling the vacuum generator through the control valve 130. For example, since the housing 100 and the cooling mechanism 110 (or the first fins 110A and the second fins 110B) of the portable hybrid heat dissipation module 10 are an integral structure, the overall structural strength of the portable hybrid heat dissipation module 10 can be increased, and incorporation with the air-tight connection between the boiling enhancement coating plate 20 and the housing 100, the vacuum generator can evacuate the two-phase chamber 101 through the fluid inlet 103 by controlling the control valve 130, so as to reduce the pressure in the two-phase chamber 101. Since the boiling temperature of the work fluid 50 is associated with the pressure, the boiling temperature of the work fluid 50 will be reduced as the pressure in the two-phase chamber 101 is reduced (such as a negative pressure). Accordingly, in the case that the pressure in the two-phase chamber 101 is adjusted (e.g. reduced) to reduce the boiling temperature of the work fluid 50, a common liquid that has a relatively high boiling temperature at the atmospheric pressure and is readily available (i.e., cheap) can be used as the work fluid 50, not limited to specific two-phase fluids with the low boiling temperature (e.g. the boiling temperature <60° C.). For example, the boiling temperature of the work fluid 50 is preferably greater than or equal to 45° C. and less than or equal to 250° C. at the atmospheric pressure. The work fluid 50 may include common liquids, such as fluoride liquid, water (e.g. deionized water), propylene glycol, or ethylene glycol in liquid phase, but not limited thereto. By adjusting the pressure in the two-phase chamber 101, the boiling temperature of the work fluid 50 is preferably adjusted from a higher temperature to a common operating temperature range, such as 60° C. to 150° C., but not limited thereto. Moreover, since the conductivity of the work fluid 50 will not affect the heat dissipation of the boiling enhancement coating plate 20, the work fluid 50 can be a dielectric fluid, semi-conductive fluid, or conductive fluid. For example, the conductivity of the conductive fluid is greater than 0.01 S/m; the conductivity of the semi-conductive fluid is in a range of 10⁻²~10² S/m; the conductivity of the dielectric fluid is lower than 10⁻⁸ S/m.

In another embodiment, the portable hybrid heat dissipation module 10 of the disclosure can be applied to a high heat flux electronic component to constitute a high heat flux electronic device. Referring to FIG. 5A, FIG. 5A is a cross-sectional view of the high heat flux electronic device 1 in an embodiment of the disclosure. As shown in FIG. 5A, the high heat flux electronic device 1 of the disclosure includes the portable hybrid heat dissipation module (e.g. 10) in any of embodiments of FIG. 1 to FIG. 4 and a high heat flux electronic component 80. The high heat flux electronic component 80 is combined with the boiling enhancement coating 210 of the boiling enhancement coating plate 20 and located outside the housing 100. Specifically, the high heat flux electronic component 80 and the boiling enhancement coating plate 20 can be combined with each other by any suitable manner, so that the boiling enhancement coating plate 20 faces toward the two-phase chamber 101 to dissipate heat generated by the high heat flux electronic component 80 to the two-phase chamber 101. For example, the high heat flux electronic component 80 can be a component having high heat flux, such as the central processing unit (CPU) or the graphic processing unit (GPU) in a server. The boiling enhancement coating plate 20 is installed on the high heat flux electronic component 80 to serve as the two-phase heat sink of the high heat flux electronic component 80. When the boiling enhancement coating plate 20 is installed on the high heat flux electronic component 80, the boiling enhancement coating 210 is preferably in contact with the heat source of the high heat flux electronic component 80, so that when the high heat flux electronic component 80 is running, the boiling enhancement coating plate 20 can dissipate heat generated by the high heat flux electronic component 80.

Referring to FIG. 5B, FIG. 5B is an exploded view of the high heat flux electronic device in an embodiment of the disclosure. As shown in FIG. 5B, in an embodiment, the high heat flux electronic component 80 can be combined with the portable hybrid heat dissipation module by the fixing member 45. Specifically, the fixing member 45 is preferably embodied as a spring screw to facilitate the connection tightness between the high heat flux electronic component 80 and the portable hybrid heat dissipation module, but not limited thereto. In other embodiments, the fixing member 45 can be a screw, a bolt, or the like. Corresponding to the fixing member 45, the portable hybrid heat dissipation module may have a through hole 102, which penetrates the housing 100A and the boiling enhancement coating plate 20, and the high heat flux electronic component 80 has a fixing hole 82 corresponding to the through hole 102. The fixing member 45 can be inserted into the through hole 102 from one side of the housing 100A and then passes through the boiling enhancement coating plate 20 to be secured to the fixing hole 82. As such, the high heat flux electronic component 80 and the portable hybrid heat dissipation module can be tightly combined with each other, and the high heat flux component (e.g. CPU, GPU) of the high heat flux electronic component 80 can be in surface-contact with the boiling enhancement coating 210 of the boiling enhancement coating plate 20 to achieve the effective heat dissipation configuration. It is noted that the housing 100A has a configuration similar to the housing 100 and is different in that the housing 100A has a recessed structure at four corners for disposing the through hole 102, but not limited thereto. In another embodiment (not shown), at least one of the housing 100 and the boiling enhancement coating plate 20 can have a protrusion structure for disposing the through hole 102. For example, at least one of the housing 100 and the boiling enhancement coating plate 20 can be formed with a wing portion or a tab portion at a side that is adjacent to the chamber opening 101′ of the two-phase chamber 101, and the wing portion or the tab portion preferably extends along the plane where the chamber opening 101′ lies and is provided for disposing the through hole 102.

As shown in FIG. 6, the high heat flux electronic component 80 is located outside the portable hybrid heat dissipation module 10, i.e., outside the two-phase chamber 101 and not in contact with the work fluid 50. Therefore, the conductivity of the work fluid 50 will not affect the operation of the high heat flux electronic component 80, so that the work fluid 50 can be a dielectric fluid, a semi-conductive fluid, or a conductive fluid. Moreover, the work fluid 50 absorbs the heat transferred by the boiling enhancement coating plate 20 from the high heat flux electronic component 80 and cooperates with the boiling enhancement coating 210 to evaporate from the liquid phase to the gas phase and form the bubbles 50a, so as to effectively dissipate heat generated by the high heat flux electronic component 80. The bubbles 50a will rise upward to be in contact with the cool surface of the cooling mechanism (e.g. the top surface of the two-phase chamber 101, the tubular coolant flowing space 116, the second fins 110B, or the like), and then condense into the droplets 50b to restore the phase before the phase change (i.e., the liquid phase). The droplets 50b fall down into the work fluid pool by gravity to achieve the high-efficiency hybrid heat dissipation through phase change and heat exchange. Moreover, by adjusting the pressure in the two-phase chamber 101 to adjust the boiling temperature of the work fluid 50, a more economical fluid can be selected as the work fluid 50 to greatly reduce the cost of the work fluid 50.

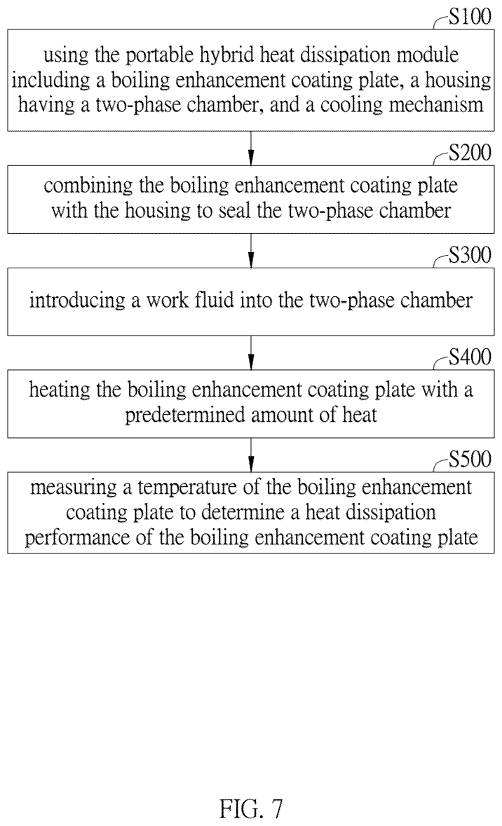

The portable hybrid heat dissipation module 10 of the disclosure in a modular configuration not only can be combined with the high heat flux electronic component to form the high heat flux electronic device, but also can be used with a heating device (e.g. 60) to test the heat dissipation performance of the boiling enhancement coating plate. Referring to FIG. 6 and FIG. 7, the operation of the portable hybrid heat dissipation module and the test method thereof in an embodiment of the disclosure are illustrated. As shown in FIG. 6 and FIG. 7, the test method of the disclosure includes a step S100, using the portable hybrid heat dissipation module (e.g. 10) of the disclosure, a step S200, combining the boiling enhancement coating plate (e.g. 20) with the housing (e.g. 100) of the portable hybrid heat dissipation module 10 to seal the two-phase chamber 101, a step S300, introducing the work fluid 50 into the two-phase chamber 101, a step S400, heating the boiling enhancement coating plate with a predetermined amount of heat, and a step S500, measuring a temperature of the boiling enhancement coating plate to determine the heat dissipation performance of the boiling enhancement coating plate.

Specifically, although the portable hybrid heat dissipation module 10 of FIG. 1A is shown in FIG. 6, the portable hybrid heat dissipation module of any of the previous embodiments can be used in the step S100. In the step S200, the boiling enhancement coating plate 20 or another boiling enhancement coating plate to be tested can be combined with the housing 100 by the coupling member (e.g. 40, 70) to enable the two-phase chamber 101 to become an air-tight space. In the step S300, the work fluid 50 is introduced into the two-phase chamber 101 through the fluid inlet 103, and the work fluid 50 is introduced up to 75% of the volume of the two-phase chamber 101, preferably about 50% of the volume of the two-phase chamber 101, to form the work fluid pool in the two-phase chamber 101. In the case that the cooling mechanism is constituted by the coolant inlet 112, the coolant outlet 114, and the coolant flowing space 116 (i.e., the cooling mechanism 110 of FIG. 1A), the test method of the disclosure further includes introducing the coolant (e.g. water) from the coolant inlet 112 before the step of heating the boiling enhancement coating plate 20, so that the coolant flows through the coolant flowing space 116 and then out of the coolant outlet 114.

After the step S200 or S300 (e.g. S300), the test method of the disclosure further includes adjusting the pressure in the two-phase chamber 101 to adjust the boiling temperature of the work fluid 50. Specifically, by connecting the fluid inlet 103 with a vacuum pump, the pressure in the two-phase chamber 101 can be adjusted, so that the boiling temperature of the work fluid 50 is preferably adjusted to a reduced temperature range, such as 60° C. to 150° C. to achieve a better heat dissipation effect, thereby expanding the applicable two-phase fluids and allowing the selection of more economical two-phase fluids, such as water, propylene glycol or ethylene glycol.

In the step S400, as shown in FIG. 6, in corporation with the heating device 60, the predetermined amount of heat is provided to heat the boiling enhancement coating plate 20. In an embodiment, the heating device 60 may include a heating block, which is disposed on the boiling enhancement coating 210 of the boiling enhancement coating plate 20, and the heating device 60 is turned on to heat the boiling enhancement coating plate 20 with predetermined watts for testing the heat dissipation performance. Since the work fluid 50 will carry the heat from the boiling enhancement coating plate 20 (e.g. the boiling enhancement coating 210), and the work fluid 50 is characterized in low boiling temperature, the work fluid 50 in the work fluid pool will experience the phase change, i.e., evaporate from the liquid phase to the gas phase, to form bubbles 50a. The bubbles 50a will rise upward to be in contact with the cool surface of the cooling mechanism, such as the top surface of the two-phase chamber 101, the tubular coolant flowing space 116, the second fins 110B, or the like, and then condense into droplets 50b, which restore the phase state before the phase change (i.e., the liquid phase). The droplets 50b will fall down into the work fluid pool by gravity. Consequently, the two-phase heat dissipation mechanism wherein the work fluid 50 receives the heat from the boiling enhancement coating plate 20 to experience the phase change, and the cooling mechanism enables the work fluid 50 to restore the phase state before the phase change, can dissipate the predetermined amount of heat provided to the boiling enhancement coating plate 20.

In the step S500, by measuring the temperature of the boiling enhancement coating plate 20, the heat dissipation performance of the boiling enhancement coating plate 20 can be determined. Specifically, a reference boiling enhancement coating plate can be used to substitute the boiling enhancement coating plate 20 to be combined with the housing 100, and the test method described above can be used to measure the temperature of the reference boiling enhancement coating plate to build a reference standard of heat dissipation performance. When the measured temperature of the boiling enhancement coating plate 20 is lower than the temperature of the reference boiling enhancement coating plate, it is determined that the heat dissipation performance of the boiling enhancement coating plate 20 is good. When the measured temperature of the boiling enhancement coating plate 20 is higher than the temperature of the reference boiling enhancement coating plate to a certain extent, it is determined that the heat dissipation performance of the boiling enhancement coating plate 20 is poor. As such, it can effectively determine that the two-phase boiling enhancement coating plate or the heat dissipation module is good or defective, improving the inspection efficiency.

Moreover, after the boiling enhancement coating plate (e.g. 20) is tested for the heat dissipation performance, the steps of removing the heating device 60, recycling the work fluid 50 in the two-phase chamber 101, removing the boiling enhancement coating plate as well as the cleaning and packaging procedures can be performed. Accordingly, the housing 100 of the portable hybrid heat dissipation module 10 can be used as the test jig for the heat dissipation performance and combined with the boiling enhancement coating plate to be tested, and the test method of the disclosure is applied to inspect the heat dissipation performance of the boiling enhancement coating plate.

In comparison with the conventional test device, since the portable hybrid heat dissipation module of the disclosure has the housing and the cooling mechanism integrated into an integral structure and designed as a compact structure for a single boiling enhancement coating plate, the volume can be greatly reduced, and the portability of the portable hybrid heat dissipation module is effectively enhanced, thereby significantly reducing the usage amount and cost of the work fluid 50 as well as the resource. Table 1 exemplarily illustrates the related values, but not limited thereto.

TABLE 1

| | | The portable hybrid |
|---|---|---|
| | | heat dissipation |
| | Conventional | module (the housing) |
| | test device | of the disclosure |
| Total dimension (mm) | 600(L) × 200(W) × | 150(L) × 50(W) × |
| | 600(H) mm | 150(H) mm |
| Overall | — | >95% |
| reduced volume | | |
| Reduced work fluid | — | >95% |
| for a single boiling | | |
| enhancement coating | | |
| plate | | |

In addition, since the portable hybrid heat dissipation module of the disclosure can adjust the boiling temperature of the work fluid by adjusting the pressure in the two-phase chamber, a more economical work fluid can be used to greatly reduce the cost of the work fluid. Table 2 exemplarily illustrates the related values, but not limited thereto.

TABLE 2

| | Conventional | | the portable hybrid heat dissipation | | |
|---|---|---|---|---|---|
| | test device | | module of the disclosure | | |
| Work fluid | two-phase fluid | | two-phase fluid | | water |
| Fluid Cost | 5,000 | NTD/liter | 5,000 | NTD/liter | about 0 NTD |
| Minimum | 12 | L | 0.5 | L | 0.5 L |
| required | | | | | |
| amount of fluid | | | | | |
| Consumed | 10% | | 30% | | 30% |
| amount | | | | | |
| of fluid per | | | | | |
| every test | | | | | |
| Cost for | 6,000 | NTD | 750 | NTD | about 0 NTD |
| consumed | | | | | |
| fluid | | | | | |

Although the preferred embodiments of the disclosure have been described herein, the above description is merely illustrative. The preferred embodiments disclosed will not limit the scope of the disclosure. Further modification of the disclosure herein disclosed will occur to those skilled in the respective arts and all such modifications are deemed to be within the scope of the disclosure as defined by the appended claims.

What is claimed is:

1. A portable hybrid heat dissipation module, comprising:
a boiling enhancement coating plate;
a housing formed with a two-phase chamber and combined with the boiling enhancement coating plate to seal the two-phase chamber; and
a cooling mechanism disposed on the housing corresponding to the two-phase chamber.

2. The portable hybrid heat dissipation module of claim 1, wherein the cooling mechanism comprises a coolant inlet, a coolant outlet, and a coolant flowing space; the coolant inlet and the coolant outlet are formed on the housing; the coolant flowing space communicates the coolant inlet with the coolant outlet and is adjacent to the two-phase chamber or located in the two-phase chamber.

3. The portable hybrid heat dissipation module of claim 1, wherein the cooling mechanism comprises a plurality of first fins disposed on the housing and located outside the two-phase chamber.

4. The portable hybrid heat dissipation module of claim 3, wherein the cooling mechanism further comprises a plurality of second fins disposed on the housing and located in the two-phase chamber.

5. The portable hybrid heat dissipation module of claim 1, further comprising a gasket, wherein the housing has a chamber opening communicating with the two-phase chamber; the gasket is disposed between the housing and the boiling enhancement coating plate and surrounds the chamber opening.

6. The portable hybrid heat dissipation module of claim 5, wherein the housing has a groove; the groove is disposed surrounding the chamber opening; the gasket is disposed in the groove.

7. The portable hybrid heat dissipation module of claim 1, further comprising a fluid inlet, wherein the fluid inlet is disposed on the housing and communicates with the two-phase chamber; the fluid inlet allows a work fluid to flow into the two-phase chamber.

8. The portable hybrid heat dissipation module of claim 7, further comprising a control valve, wherein the control valve is disposed on the housing corresponding to the fluid inlet and controls communication of the two-phase chamber with an external environment through the fluid inlet.

9. The portable hybrid heat dissipation module of claim 7, wherein the fluid inlet selectively functions as a gate to adjust a pressure in the two-phase chamber.

10. The portable hybrid heat dissipation module of claim 1, further comprising a coupling member combining the housing with the boiling enhancement coating plate to enable the two-phase chamber to become an air-tight space.

11. The portable hybrid heat dissipation module of claim 10, wherein the boiling enhancement coating plate comprises a boiling enhancement coating and a frame; the frame supports the boiling enhancement coating; the coupling member fixes the frame on the housing.

12. The portable hybrid heat dissipation module of claim 10, wherein the coupling member comprises a screw, a locking member, or a combination thereof.

13. A high heat flux electronic device, comprising:
the portable hybrid heat dissipation module of claim 1; and
a high heat flux electronic component combined with the boiling enhancement coating plate and located outside the housing.

14. The high heat flux electronic device of claim 13, wherein the portable hybrid heat dissipation module further comprises a fluid inlet; the fluid inlet is disposed on the housing and communicates with the two-phase chamber; the fluid inlet selectively functions as a gate to adjust a pressure in the two-phase chamber.

15. The high heat flux electronic device of claim 13, wherein the boiling enhancement coating plate comprises a boiling enhancement coating and a frame; the frame supports the boiling enhancement coating and is fixed on the housing; the high heat flux electronic component is combined with the boiling enhancement coating.

16. A test method of a portable hybrid heat dissipation module, comprising:
using the portable hybrid heat dissipation module of claim 1;
combining the boiling enhancement coating plate with the housing to seal the two-phase chamber;
introducing a work fluid into the two-phase chamber;
heating the boiling enhancement coating plate with a predetermined amount of heat; and
measuring a temperature of the boiling enhancement coating plate to determine a heat dissipation performance of the boiling enhancement coating plate.

17. The test method of claim 16, wherein in the step of introducing the work fluid, the work fluid is introduced up to 75% of a volume of the two-phase chamber.

18. The test method of claim 16, wherein the step of introducing the work fluid comprises introducing a dielectric fluid, semi-conductive fluid, or conductive fluid with a boiling temperature greater than or equal to 45° C. and less than or equal to 250° C. at an atmospheric pressure.

19. The test method of claim 18, wherein the step of introducing the work fluid comprises introducing fluoride liquid, water, propylene glycol, or ethylene glycol in liquid phase.

20. The test method of claim 16, further comprising adjusting a pressure in the two-phase chamber to adjust a boiling temperature of the work fluid.
